(19) United States
(12) Patent Application Publication
(10) Pub. No.: US 2011/0259411 A1
(43) Pub. Date: Oct. 27, 2011

(54) PACKAGING STRUCTURE AND PROCESS OF SOLAR CELL

(75) Inventor: Tai Hui LIU, Hsinchu County (TW)

(73) Assignee: SOLAPOINT CORPORATION, Hsinchu County (TW)

(21) Appl. No.: 12/767,333

(22) Filed: Apr. 26, 2010

(51) Int. Cl. H01L 31/12; H01L 31/18

(52) U.S. Cl. 136/256; 438/64; 257/E31.113; 257/E31.11

(57) ABSTRACT

A packaging structure and process of solar cell is disclosed. The packaging structure of solar cell comprises two conductive films and two surface electrodes disposed on a photovoltaic cell (PV cell), wherein two conductive films are respectively electrically coupled with the surface electrodes via a plurality of solder balls.

### BACKGROUND OF THE INVENTION

1. Field of the Invention

The present invention is generally related to a packaging structure and process of solar cell.

2. Description of the Prior Art

Energy generated from solar cells is considered more eco-friendly than other energy sources, such as fossil energy, nuclear energy, water, etc. Lots of advantages of solar power gradually turn up, especially when the crude oil prices continue to shoot up. Furthermore, the crude oil will be exhausted one day, and the solar power, relative to crude oil is concerned the inexhaustible source of energy. Therefore, governments, research institute and many private enterprises have invested many time and resources in solar energy development.

In general, the solar cell generates voltage difference between two-terminal electrodes of p-n diodes struck by photons, wherein each electron-hole pair generated from a semiconductor struck by photons separates due to the internal electric field formed between p-n junction, and electrons and holes respectively move to the two-terminal electrodes in the opposite directions.

Solar cells are generally related with the p-n diode. For example, n-type silicon is doped by V family elements (such as phosphate) as the donor to provide electrons, and p-type silicon is doped by III family elements (such as boron) as the acceptor to provide holes. Accordingly, there could be four kind of electrical particles in semiconductor: electrons with negative charge, electrical holes with positive charge, acceptor ions with negative charge and donor ions with positive charge. The former two kinds of particle are movable, but the latter two kinds of particle are not.

N-type or p-type semiconductor maintains charge neutrality before had been exposed. In other words, positive charges of the donor ions approximately equal to negative charges of electrons (majority carriers in n-type semiconductor) in n-type semiconductor. In p-type semiconductor, negative charges of acceptor ions approximately equal to positive charges of electrical holes (majority carriers in p-type semiconductor).

The p-n junction is a boundary between a p-type and n-type semiconductor. Near the junction, electrons diffuse to p-type region (low concentration of electrons) from n-type region (high concentration of electrons), and electrical holes diffuse to n-type region (low concentration of electrical holes) from p-type region (high concentration of electrical holes). Thus, the neutral will not able to be remained around the junction.

Positive charge region will be generated because donor ions are exposed at n-type region near the junction, and negative charge region will be generated because acceptor ions are exposed at p-type region near the junction. Both the positive charge region in n-type region and the negative charge region in p-type region are named space charge region.

Because positive donor ions and negative acceptor ions are fixed in the lattice, a built-in electrical field will be formed at the n-type and p-type regions. The direction of the built-in electrical field in the space charge region points towards the p-type region from the n-type region.

If incident photons are absorbed in the space charge region to produce electron-hole pairs, the electrons will drift to n-type region along the built-in electrical field, and electrical holes will drift to p-type region along the built-in electrical field.

The drift current moving to p-type region from n-type region due to the built-in electrical field is so-called photocurrent. The photocurrent of the solar cell flowing to p-type region from n-type region is exactly the current direction of the reverse bias in a p-n diode.

In solar cells, electron-hole pairs are separated to generate photocurrent before recombination. Then the photocurrent is outputted to a load via metal contact of p-n diode. It is the basic working principle of solar cell (photovoltaic cell or PV cell).

### SUMMARY OF THE INVENTION

Therefore, in accordance with the previous summary, objects, features and advantages of the present disclosure will become apparent to one skilled in the art from the subsequent description and the appended claims taken in conjunction with the accompanying drawings.

According to the issues raised from the prior art and accommodating to requirement of industrial benefit, this invention provides a packaging structure and process of solar cell. The major character of the invention is replacing the traditional welding with hot laminating by a plurality of solder balls.

Accordingly, the invention discloses a packaging structure of solar cell, including two surface electrodes and two conductive films. Two surface electrodes are disposed on a PV (photovoltaic) cell and two conductive films are respectively electrically coupled with the surface electrodes via a plurality of solder balls.

The invention further discloses a packaging process of solar cell, including the following steps: disposing a plurality of solder balls on two surface electrodes of a PV cell, wherein the PV cell is disposed on a substrate; and hot laminating at least one conductive film and the surface electrodes by said plurality of solder balls.

### BRIEF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1A and FIG. 1B illustrate a packaging structure of solar cell of the present invention; and

FIG. 2 illustrates a flow chart of a packaging process of solar cell of the present invention.

### DETAILED DESCRIPTION OF THE PREFERRED EMBODIMENTS

The present disclosure can be described by the embodiments given below. It is understood, however, that the embodiments below are not necessarily limitations to the present disclosure, but are used to a typical implementation of the invention.

Having summarized various aspects of the present invention, reference will now be made in detail to the description of the invention as illustrated in the drawings. While the invention will be described in connection with these drawings, there is no intent to limit it to the embodiment or embodiments disclosed therein. On the contrary the intent is to cover all alternatives, modifications and equivalents included within the spirit and scope of the invention as defined by the appended claims.

It is noted that the drawings presented herein have been provided to illustrate certain features and aspects of embodiments of the invention. It will be appreciated from the description provided herein that a variety of alternative embodiments and implementations may be realized, consistent with the scope and spirit of the present invention.

It is also noted that the drawings presented herein are not consistent with the same scale. Some scales of some components are not proportional to the scales of other components in order to provide comprehensive descriptions and emphases to this present invention.

Solar cells need Surface electrodes (bus bar) to connect outside circuits. In general, both the Shading surface and the Open surface of a solar cell have two parallel strip surface electrodes to provide the weld connection place for the outside circuits. The Shading surface is usually coated a well-known “back surface field (BSF)” metal layer, then two parallel strip surface electrodes are disposed on the BSF; while each of the strip surface electrodes of the Open surface are connected by a plurality of parallel metal grid lines. BSF metal layer can increase the collection amount of carriers, and recycle the unabsorbed photons. On the other hand, the design of grid lines, in addition to the effective collection of carriers, but also to minimize the proportion of incident light shielded off by grid lines. In average, the grid lines on the Open surface shield 3% to 5% of the incident light.

The material of the surface electrodes comprises Ni, Ag, Al, Cu, or Pd. For preventing shading the solar cell from the incident sun light, the configuration design of the surface electrodes will play an important role. The electrodes should be thick enough to facilitate the current conduction; however, the area of the electrodes should be small to avoid shading. Therefore, parallel metal grid lines are proposed to connect adjacent surface electrodes on the Open surface.

Metal grid lines, like tree branches, spread on the surface of the solar cell to increase the current reception area, and the tree branches are also small enough to prevent most area of the solar cell to be covered. Furthermore, the surface electrodes, like the trunk of the trees, collect the current from the metal grid lines and output the current to the outside circuit. It is noted that the design of the trunk is thick to reduce the resistance.

Traditionally, the surface electrodes output current to the outside circuit via a plurality of I/O conducting wires (bridge). Because the conducting wires usually consist of high melting point metal such as Ag, the high operation temperature for welding is easy to cause damage of solar cells. Moreover, the I/O conducting wire welding, with manually positioned and cut, is a very inefficient process. If any conducing wire fails in welding, the conducting wire fails to output current. Because conventional welding processes very close to “handmade industry”, it is difficult to raise yield rate and mass production.

In view of the foregoing problems, this invention replaces the traditional welding process with hot laminating the conductive film and the surface electrodes by tin solder balls. The advantage of hot laminating process is not easy to damage the semiconductor structure because the melting point of tin is lower. On the other hand, if tin is entirely covered the whole surface electrodes, the stress problems will raise and result in deformed structure. In the present invention, the surface electrodes and the conductive film are bonded by the matrix of the solder balls to avoid structure damaged by stress. Additionally, the conductivity between the surface electrodes and the conductive film could be obviously improved even without precise alignment by the matrix of the solder balls formed by BGA (Ball Grid Array) method. Because the number of the solder balls is large and the solder balls are densely arranged, the conductivity will not be reduced even if some solder balls don't touch the conductive film or contact with each other. By using these means, mass production and yield rate could be raised, and the process and cost could be reduced.

Please referring to the drawings, detailed descriptions, technical elements and a variety of embodiments will be provided as follows.

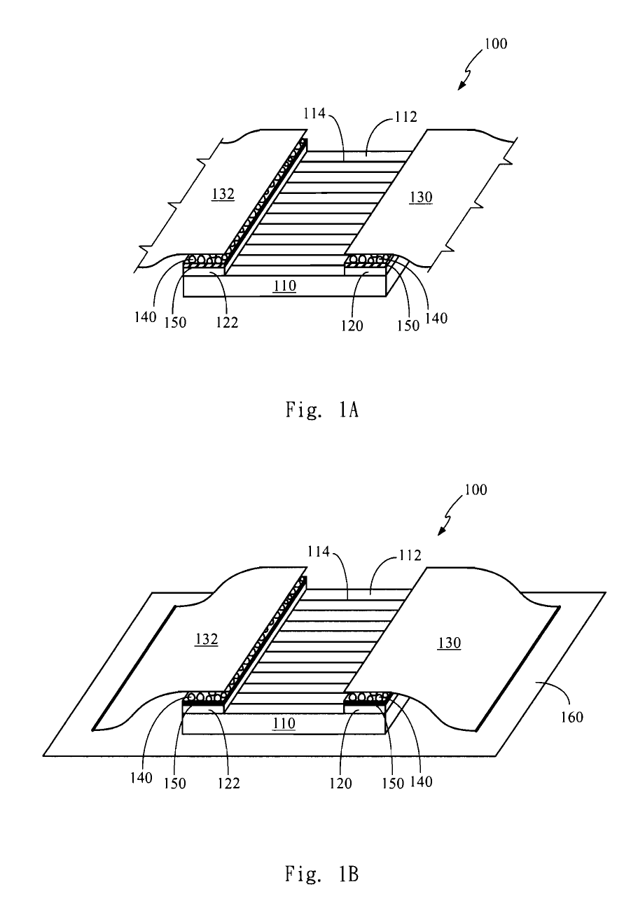

Please refer to FIG. 1A, a package structure of a solar cell 100 is disclosed in the present invention. The package structure of the solar cell 100 includes a PV (photovoltaic) cell 110, two surface electrodes 120, 122 and two conductive films 130, 132. The surface electrodes 120, 122 are disposed on the PV cell 110, and are respectively located on the opposite sides of the window layer 112 of the PV cell 110.

One end of the conductive film 130 is electrically coupled with the corresponding surface electrode 120 via a plurality of solder balls 140, and the other end of the conductive film 130 extends outside the window layer 112 to avoid shading the window layer 112. Similarly, one end of the conductive film 132 is also electrically coupled with the corresponding surface electrode 122 via a plurality of solder balls 140, and the other end of the conductive film 132 extends outside the window layer 112 to expose the window layer 112. The window layer 112 includes a plurality of grid lines 114 to effectively collect electrical carriers. The proportion of incident light shielded by the grid lines should be reduced because the window layer 112 is on the Open surface of a solar cell.

For avoiding the solder balls 140 penetrating the surface electrode 120, 122, a barrier layer 150 could be located between the surface electrodes 120, 122 and solder balls 140. By protection from the barrier layer 150, it could be avoided that solder balls 140 pollute the surface electrodes 120, 122.

Please refer to FIG. 1B, the package structure of the solar cell 100 further comprise a substrate 160, and the PV cell 110 is disposed on the substrate 160. The window layer 112 of the PV cell 110 and the substrate 160 are respectively located at the upper and lower surfaces of the PV cell 110, and the ends of the conductive films 130, 132 not connected with the surface electrodes 120, 122 are electrically coupled with the substrate 160.

This invention further discloses a package process of a solar cell, including the following steps: at first, as step 210, disposing a plurality of solder balls 140 on two surface electrodes 120, 122 of a PV cell 110, disposed on a substrate 160; subsequently, as step 220, hot laminating a conductive film 134 and the surface electrodes 120, 122; and finally, as step 230, removing part of the conductive film 134 to form the conductive films 130, 132, wherein the part of the conductive film 134 covers the window layer 112 of the PV cell 110 before being removed.

For protecting the surface electrodes 120, 122 from being polluted by the solder balls 140, the package process of the solar cell further includes a step 202, forming a barrier layer 150 on the surface electrodes 120, 122 before step 210. Consequently, the package process of the solar cell disclosed in this invention could also comprise the following steps: at first, as step 202, forming the barrier layer 150 on the surface electrodes 120, 122; then, as step 210, disposing solder balls 140 on surface electrodes 120, 122, wherein the barrier layer 150 is located between solder balls 140 and the surface electrodes 120, 122; subsequently, as step 220, hot laminating the conductive film 134 and the surface electrodes 120, 122; and finally, as step 230, removing part of the conductive film 134 covering the window layer 112 of the PV cell 110 to form the conductive films 130, 132.

Furthermore, the package process of the solar cell further includes the step of respectively connecting the two ends of the conductive film 134 to the substrate 160. This step could be executed simultaneously with step 220, or be executed after step 220. Otherwise, this step could be executed simultaneously with step 230, or executed after step 230. In view of the above, the package process of the solar cell could respectively be described as follows.

Method I: at first, as step 202, forming the barrier layer 150 on the surface electrodes 120, 122; then, as step 210, disposing solder balls 140 on surface electrodes 120, 122; subsequently, as step 220, hot laminating the conductive film 134 and the surface electrodes 120, 122 and simultaneously connect two ends of the conductive film 134 respectively to the substrate 160; and finally, as step 230, removing part of the conductive film 134 covering the window layer 112 of the PV cell 110 to form the conductive films 130, 132.

Method II: at first, as step 202, forming the barrier layer 150 on the surface electrodes 120, 122; then, as step 210, disposing solder balls 140 on surface electrodes 120, 122; subsequently, as step 220, respectively connect two ends of the conductive film 134 to the substrate 160 after hot laminating the conductive film 134 and the surface electrodes 120, 122; and finally, as step 230, removing part of the conductive film 134 covering the window layer 112 of the PV cell 110 to form the conductive films 130, 132.

Method III: at first, as step 202, forming the barrier layer 150 on the surface electrodes 120, 122; then, as step 210, disposing solder balls 140 on surface electrodes 120, 122; subsequently, as step 220, hot laminating the conductive film 134 and the surface electrodes 120, 122; and finally, as step 230, removing part of the conductive film 134 covering the window layer 112 of the PV cell 110 to form the conductive films 130, 132 and simultaneously connect two ends of the conductive film 134 respectively to the substrate 160.

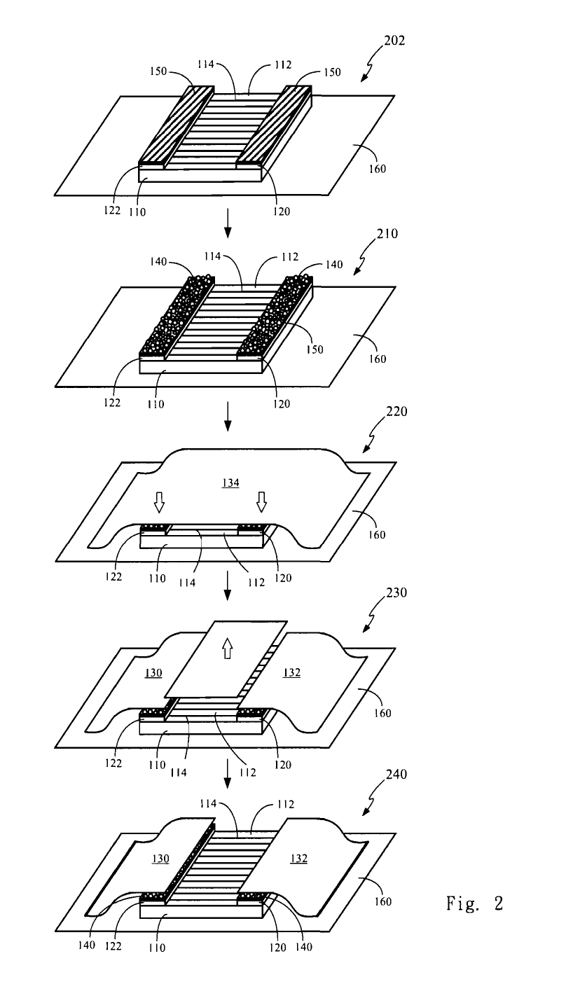

Method IV: please refer to FIG. 2, which is a flow chart of the preferred embodiment of this invention. At first, as step 202, forming the barrier layer 150 on the surface electrodes 120, 122, wherein the surface electrodes 120, 122 are disposed on the PV cell 110, and respectively located at the opposite sides of the window layer 112 of the PV cell 110; then, as step 210, disposing solder balls 140 on surface electrodes 120, 122; subsequently, as step 220, hot laminating the conductive film 134 and the surface electrodes 120, 122; next, as step 230, removing part of the conductive film 134 covering the window layer 112 of the PV cell 110 to form the conductive films 130, 132, wherein the window layer 112 includes a plurality of metal grid lines 114 to effectively collect electrical carriers; and finally, as step 240, respectively connect two ends of the conductive film 130, 132 not electrically connected with the surface electrodes to the substrate 160.

Besides removing the part of the window layer 112 of the PV cell 110 to expose the window layer 112, two conductive films 120, 122 could further be respectively hot laminated on two surface electrodes 120, 122 to avoid shading the window layer 112. Accordingly, the package process of the solar cell could include the following steps: at first, forming the barrier layer 150 on the surface electrodes 120, 122; then, disposing solder balls 140 on surface electrodes 120, 122; subsequently, hot laminating at least one conductive film and the surface electrodes (i.e. simultaneously or respectively hot laminating conductive films 130, 132 and surface electrodes 120, 122 in turn, or removing the part of the conductive film covering the window layer 112 of the PV cell 110 after hot laminating a conductive film 134 and the surface electrodes 120, 122); and finally, respectively connect two ends of the conductive film 130, 132 not electrically connected with the surface electrodes 120, 122 to the substrate 160.

The solder balls 140 could be disposed by BGA (Ball Grid Array) method. The diameter of the solder balls ranges from 100 to 150 μm, and the pitch between the solder balls 140 is about 200 μm. At ideal state, solder balls are separated from each other to keep at intervals to avoid increasing electric resistance due to the connected solder balls. One of the advantages in the present invention is that, even if some solder balls connected to one another, the resistance will not be significantly enhanced and the conductivity could be still maintained due to the large number of solder balls with small volume.

In addition, the diameter of each solder ball could be the same to avoid lowering the conductivity because some solder balls with smaller diameter can not come into contact with the conductive film in the hot laminating processes. Another advantage of the present invention is that, the conductive film is electrically coupled with a large number of solder balls to avoid lowering conductivity due to some solder balls not come in contact with the conductive film.

Furthermore, the surface electrodes 120, 122 could include one or any combination selected from the group consisting of Ni, Ag, Al, Cu, Pd. The conductive films could include one or any combination selected from the group consisting of Ni, Ag, Al, Cu, Pd.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the inventions as determined by the appended claims when interpreted in accordance with the breath to which they are fairly and legally entitled.

It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

1. A packaging structure of a solar cell, comprising:
two surface electrodes, disposed on a PV (photovoltaic) cell; and
two conductive films, respectively electrically coupled with said surface electrodes via a plurality of solder balls.

2. A packaging structure of a solar cell according to claim 1, wherein said two surface electrodes are respectively located on the opposite sides of the window layer of said PV cell, wherein one end of each conductive film is electrically coupled with one corresponding electrode, and the other end extends outside the window layer to expose said window layer.

3. A packaging structure of a solar cell according to claim 2, further comprising a substrate, and said PV cell is disposed on said substrate, wherein said window layer and said substrate are respectively located at the upper and lower surfaces of said PV cell, and the other end of each conductive film is electrically coupled with said substrate.

4. A packaging structure of a solar cell according to claim 1, further comprising a barrier layer between said solder balls and said surface electrodes to prevent said solder balls penetrating said surface electrodes, wherein said surface electrodes or said conductive films independently comprise one or any combination selected from the group consisting of Ni, Ag, Al, Cu, Pd.

5. A packaging structure of a solar cell according to claim 1, wherein the diameter of said solder balls ranges from about 100 to 150 μm, and the pitch between said solder balls is about 200 μm.

6. A packaging process of a solar cell, comprising the following steps:
disposing a plurality of solder balls on two surface electrodes of a PV (photovoltaic) cell, wherein said PV cell is disposed on a substrate; and
hot laminating at least one conductive film and said surface electrodes by said plurality of solder balls.

7. A packaging process of a solar cell according to claim 6, further comprising the following step:
removing part of said conductive film covering said window layer of said PV cell to form two conductive films, wherein one end of each conductive film is electrically coupled with one corresponding surface electrode, and the other end extends outside the window layer to expose said window layer.

8. A packaging process of a solar cell according to claim 7, further comprising the following step:
connecting respectively two ends of said conductive film to said substrate simultaneously when said conductive film and said surface electrodes are hot laminated, wherein said window layer and said substrate are respectively located at the upper and lower surfaces of said PV cell.

9. A packaging process of a solar cell according to claim 7, further comprising the following step:
connecting respectively two ends of said conductive film to said substrate after said conductive film and said surface electrodes are hot laminated, wherein said window layer and said substrate are respectively located at the upper and lower surfaces of said PV cell.

10. A packaging process of a solar cell according to claim 7, further comprising the following step:
connecting respectively two ends of said conductive film to said substrate simultaneously when said part of said conductive film is removed, wherein said window layer and said substrate are respectively located at the upper and lower surfaces of said PV cell.

11. A packaging process of a solar cell according to claim 7, further comprising the following step:
connecting respectively two ends of said conductive film to said substrate after said part of said conductive film is removed, wherein said window layer and said substrate are respectively located at the upper and lower surfaces of said PV cell.

12. A packaging process of a solar cell according to claim 6, further comprising the following step:
forming a barrier layer on said surface electrodes before said solder balls are disposed on said surface electrodes.

13. A packaging process of a solar cell according to claim 6, wherein said solder balls could be disposed by BGA (Ball Grid Array) method, wherein the diameter of said solder balls ranges from about 100 to 150 μm, and the pitch between said solder balls is about 200 μm.

14. A packaging process of a solar cell according to claim 6, wherein said surface electrodes comprise one or any combination selected from the group consisting of Ni, Ag, Al, Cu, Pd, and said conductive films comprise one or the combination selected from the group consisting of Ni, Ag, Al, Cu, Pd.
